(19) United States
(12) Patent Application Publication
(10) Pub. No.: US 2019/0047847 A1
(43) Pub. Date: Feb. 14, 2019

(54) MEMS DEVICES AND PROCESSES

(71) Applicant: Cirrus Logic International Semiconductor Ltd., Edinburgh (GB)

(72) Inventors: Aleksey Sergeyevich KHENKIN, Nashua, NH (US); Tsjerk Hans HOEKSTRA, Balerno (GB); Colin Robert Jenkins, Linlithgow (GB)

(73) Assignee: Cirrus Logic International Semiconductor Ltd., Edinburgh (GB)

(21) Appl. No.: 16/052,006

(22) Filed: Aug. 1, 2018

Related U.S. Application Data
(60) Provisional application No. 62/544,148, filed on Aug. 11, 2017.

(30) Foreign Application Priority Data
Sep. 7, 2017 (GB) 1714384.3

(51) Int. Cl. B81B 7/02; B81B 3/00; B81B 7/00; H04R 1/08

(52) U.S. Cl. CPC B81B 7/02; B81B 3/0018; B81B 7/0032; H04R 1/08; H04R 2201/003; B81B 2203/0315; B81B 2203/04; B81B 2203/0127; B81B 2201/04; B81B 2201/0257

(57) ABSTRACT

A MEMS transducer configured to operate as a microphone, the MEMS transducer comprising a flexible membrane, the flexible membrane having a first surface and a second surface, wherein the first surface of the flexible membrane is fluidically isolated from the second surface of the flexible membrane. Also, a MEMS device comprising a MEMS transducer, an electronic device comprising a MEMS transducer and/or a MEMS device, and a method for forming a MEMS device.

### TECHNICAL FIELD

This application relates to micro-electro-mechanical system (MEMS) devices and processes, and in particular to a MEMS device and process relating to a transducer, for example a capacitive microphone or an optical microphone.

### BACKGROUND INFORMATION

MEMS devices are becoming increasingly popular. MEMS transducers, and especially MEMS capacitive microphones, are increasingly being used in portable electronic devices such as mobile telephone and portable computing devices.

Microphone devices formed using MEMS fabrication processes typically comprise one or more moveable membranes and a static backplate, with a respective electrode deposited on the membrane(s) and backplate, wherein one electrode is used for read-out/drive and the other is used for biasing. A substrate supports at least the membrane(s) and typically the backplate also. In the case of MEMS pressure sensors and microphones the read out is usually accomplished by measuring the capacitance between the membrane and backplate electrodes. In the case of transducers, the device is driven, i.e. biased, by a potential difference provided across the membrane and backplate electrodes.

FIGS. 1A and 1B show a schematic diagram and a perspective view, respectively, of a known capacitive MEMS microphone device 100. The capacitive microphone device 100 comprises a membrane layer 101 which forms a flexible membrane which is free to move in response to pressure differences generated by sound waves. A first electrode 102 is mechanically coupled to the flexible membrane, and together they form a first capacitive plate of the capacitive microphone device. A second electrode 103 is mechanically coupled to a generally rigid structural layer or back-plate 104, which together form a second capacitive plate of the capacitive microphone device. In the example shown in FIG. 1A the second electrode 103 is embedded within the back-plate structure 104.

The capacitive microphone is formed on a substrate 105, for example a silicon wafer which may have upper and lower oxide layers 106, 107 formed thereon. A cavity 108 in the substrate and in any overlying layers (hereinafter referred to as a substrate cavity) is provided below the membrane, and may be formed using a “back-etch” through the substrate 105. The substrate cavity 108 connects to a first cavity 109 located directly below the membrane. These cavities 108 and 109 may collectively provide an acoustic volume thus allowing movement of the membrane in response to an acoustic stimulus. Interposed between the first and second electrodes 102 and 103 is a second cavity 110. A plurality of holes, hereinafter referred to as bleed holes 111, connect the first cavity 109 and the second cavity 110. The bleed holes act to equalise the pressure between the first cavity 109 and the second cavity 110, and may also be referred to as pressure equalisation holes.

A plurality of acoustic holes 112 are arranged in the back-plate 104 so as to allow free movement of air molecules through the back plate, such that the second cavity 110 forms part of an acoustic volume with a space on the other side of the back-plate. The membrane 101 is thus supported between two volumes, one volume comprising cavities 109 and substrate cavity 108 and another volume comprising cavity 110 and any space above the back-plate. These volumes are sized such that the membrane can move in response to the sound waves entering via one of these volumes. Typically the volume through which incident sound waves reach the membrane is termed the “front volume” with the other volume being referred to as a “back volume”. Typically, for MEMS microphones and the like, the first and second volumes are connected by one or more flow paths, such as small holes in the membrane, that are configured so as present a relatively high acoustic impedance at the desired acoustic frequencies but which allow for low-frequency pressure equalisation between the two volumes to account for pressure differentials due to temperature changes or the like.

In some applications the backplate may be arranged in the front volume, so that incident sound reaches the membrane via the acoustic holes 112 in the backplate 104. In such a case the substrate cavity 108 may be sized to provide at least a significant part of a suitable back-volume. In other applications, the microphone may be arranged so that sound may be received via the substrate cavity 108 in use, i.e. the substrate cavity forms part of an acoustic channel to the membrane and part of the front volume. In such applications the backplate 4 forms part of the back-volume which is typically enclosed by some other structure, such as a suitable package.

It should also be noted that whilst FIGS. 1A and 1B shows the backplate being supported on the opposite side of the membrane to the substrate, arrangements are known where the backplate is formed closest to the substrate with the membrane layer supported above it.

In use, in response to a sound wave corresponding to a pressure wave incident on the microphone, the membrane is deformed slightly from its equilibrium or quiescent position. The distance between the membrane electrode 102 and the backplate electrode 103 is correspondingly altered, giving rise to a change in capacitance between the two electrodes that is subsequently detected by electronic circuitry (not shown).

The membrane layer and thus the flexible membrane of a MEMS transducer generally comprises a thin layer of a dielectric material—such as a layer of crystalline or polycrystalline material. The membrane layer may, in practice, be formed by several layers of material which are deposited in successive steps. Thus, the flexible membrane 101 may, for example, be formed from silicon nitride Si₃N₄ or polysilicon. Crystalline and polycrystalline materials have high strength and low plastic deformation, both of which are highly desirable in the construction of a membrane. The membrane electrode 102 of a MEMS transducer is typically a thin layer of metal, e.g. aluminium, which is typically located in the centre of the flexible membrane 101, i.e. that part of the membrane which displaces the most. It will be appreciated by those skilled in the art that the membrane electrode may be formed by depositing a metal alloy such as aluminium-silicon for example. The membrane electrode may typically cover, for example, around 40% of area of the membrane, usually in the central region of the membrane.

In MEMS microphones, one of the key considerations is the signal-to-noise ratio (SNR) provided by the microphone. As technology develops, MEMS microphones are increasingly being called upon to record intelligible sound (such as spoken words) at larger distances. While MEMS existing MEMS microphones provide excellent recording capabilities at short distances (such as a person speaking into the microphone of a telephone while holding the telephone), the clarity of the recorded sound signal decreases rapidly with increasing source to microphone separation. Evolution in the uses of MEMS microphones, such as increasing use of “hands-free” devices with telephones and the advent of voice-controlled intelligent personal assistant services, requires that the capabilities of MEMS microphones increase so that sound can be accurately received at larger source to microphone separations.

Reducing the level of noise on a signal (and thereby improving the SNR) can improve the accuracy of recorded sound. Some sources of noise, such as echoes from hard surfaces around a MEMS device and other noise sources in the vicinity of a person speaking, cannot be removed by modifying the MEMS device. However, a further category of noise sources are inherent to the MEMS device itself; the impact of these noise sources can potentially be reduced or eliminated by modifying the MEMS device.

Noise can be generated within the structure of the MEMS device by the impact of air molecules on solid structures within the MEMS device. FIG. 2 shows a schematic of a MEMS device (MEMS microphone), comprising a MEMS transducer configured to operate as a microphone and encased within a package, and identifies potential noise sources within the MEMS microphone.

Some of the noise sources identified in FIG. 2 occur due to the interaction of air molecules with one surface or each other, such as the boundary layer noise resulting from the impact of air molecules on the exposed surfaces of structures within the MEMS microphone and the acoustic thermal noise due to the collisions of the air molecules with one another. However, the dominant sources of noise within MEMS microphones are typically due to the movement of air molecules through a comparatively narrow gap. Examples of these noise sources are the movement of air molecules through gaps in the back plate (back plate noise) or between the back plate and the flexible membrane surface (air gap noise). In particular, where acoustic holes 112 are present in the back plate (see FIG. 1A) these can result in noise generation. Acoustic phase noise can also be generated by bleed holes 111 connecting the front volume to the back volume.

The present disclosure relates to MEMS transducers configured to operate as microphones which aim to reduce the impact of noise sources, and thereby provide improved SNRs.

### SUMMARY

According to an example embodiment of an aspect there is provided a MEMS transducer configured to operate as a microphone the MEMS transducer comprising a flexible membrane, the flexible membrane having a first surface and a second surface, wherein the first surface of the flexible membrane is fluidically isolated from the second surface of the flexible membrane. The fluidic isolation of the first surface of the flexible membrane from the second surface of the flexible membrane can help reduce the impact of noise sources within the MEMS device, thereby improving the SNR.

The flexible membrane of the MEMS transducer may comprise an electromagnetic waveguide, and the MEMS transducer may be configured to operate as an optical microphone (that is, a microphone using an optical sensing system). Use of optical sensing systems comprising electromagnetic waveguides may allow additional noise sources to be avoided, and can also provide sensitive measurements of the flexible membrane position.

A plane of the flexible membrane may be circular, and/or the flexible membrane may have a dome shape. Both of these features can improved the resilience of the membrane to damage, particularly damage due to pressure differentials across the membrane.

The MEMS transducer may further comprise a chamber, or a MEMS device may comprise the MEMS transducer and also comprise a chamber. The second surface of the flexible membrane may partially defines the boundary of the chamber, and the chamber may be fluidically isolated from a region outside the chamber. In particular, the chamber may be the back volume of the microphone. Use of a sealed chamber partially defined by the second surface of the flexible membrane allows noise sources, such as the passage of air through bleed holes in the membrane, to be eliminated.

The chamber may contain a constant amount of gas, which may be substantially zero gas (that is, a vacuum), or which may be an amount of gas set such that the chamber is at a lower pressure than a region outside the chamber (such as approximately 1 kgm⁻¹ s⁻² when the MEMS transducer is at standard temperature and pressure). Reducing (or eliminating) the gas in the chamber may reduce noise by reducing the number of collisions of the gas molecules with the perimeter of the chamber.

The gas in the chamber may be a gas having a lower mean molecular weight than air, such as helium. Use of a low mean molecular weight gas reduces the average kinetic energy of the gas molecules relative to higher weight molecules, and thereby reduces noise due to collisions of the gas molecules with the perimeter of the chamber.

Where the MEMS device comprises the chamber which is the back volume of the microphone, the back volume may be partially defined by the flexible membrane and a substrate of the MEMS device. The substrate may comprise a layer including at least a portion of the electronic circuitry of the microphone, the MEMS device being configured such that the flexible membrane at least partially (and preferably fully) overlies the portion of the electronic circuitry. In this way, the components of the MEMS device can be efficiently arranged and the total size of the MEMS device can be reduced.

The back volume may be partially defined by a package of the MEMS device, providing a configuration of the microphone which may be suited for some applications of the microphone.

The package may be a laminate type package or may be a lid type package. Laminate type packages allow parallel processes to be used to efficiently form large numbers of MEMS devices comparatively quickly and inexpensively (when compared to production not utilising parallel processes). Lid type packages are simpler to produce and may be particularly suitable if it is desired to produce a small number of MEMS devices.

According to an example embodiment of a further aspect there is provided a MEMS transducer comprising a flexible membrane wherein the flexible membrane is unperforated. The absence of perforations in the flexible membrane may prevent gas passing through the membrane, thereby reducing noise generated if the MEMS transducer is used as a microphone.

According to an example embodiment of a further aspect there is provided packaged MEMS optical microphone comprising a flexible membrane, the flexible membrane having a first surface and a second surface, the packaged MEMS optical microphone being configured such that the first surface of the flexible membrane is fluidically isolated from the second surface of the flexible membrane. According to a further example embodiment of a further aspect there is provided a MEMS capacitive transducer configured to operate as a microphone, the MEMS transducer comprising a flexible membrane, the flexible membrane having a first surface and a second surface, the MEMS capacitive transducer being configured such that the first surface of the flexible membrane is fluidically isolated from the second surface of the flexible membrane. The fluidic isolation of the first surface of the flexible membrane from the second surface of the flexible membrane allows the elimination of noise sources which can reduce the SNR of the microphone.

Features of any given aspect may be combined with the features of any other aspect and the various features described herein may be implemented in any combination in a given embodiment.

Associated methods of fabricating a MEMS transducer are provided for each of the above aspects and examples described herein.

### FIGURES

The invention is described, by way of example only, with reference to the following Figures, in which:

FIG. 1A is a schematic view of a known MEMS capacitive microphone device.

FIG. 1B is a perspective view of a known MEMS capacitive microphone device.

FIG. 2 is a schematic of a MEMS device identifying potential noise sources.

FIG. 3 is a schematic of a MEMS device including a capacitive sensing system.

FIG. 4 is a schematic of a MEMS device including an optical sensing system.

FIG. 5A is a schematic of an optical sensing system.

FIG. 5B illustrates the operating principle of the optical sensing system of FIG. 5A.

FIG. 6 is a schematic of a further optical sensing system.

FIG. 7 is an outline plot illustrating the variation in recorded intensity with separation for optical and capacitive systems.

FIG. 8A is a schematic view of a MEMS device comprising a lid type package.

FIG. 8B is a schematic view of a further MEMS device comprising a lid type package.

FIG. 9A is a cross-section of a MEMS device comprising a laminate type package.

FIG. 9B is a plan view of a layer for use in forming a plurality of MEMS devices with laminate type packages.

FIG. 10A is a schematic of a MEMS device having a lid type package and a pressure differential across the flexible membrane.

FIG. 10B is a schematic of a further MEMS device having a lid type package and a pressure differential across the flexible membrane.

FIG. 11 is a schematic of a MEMS device having a laminate type package, an optical sensing system and a pressure differential across the flexible membrane

### DETAILED DESCRIPTION

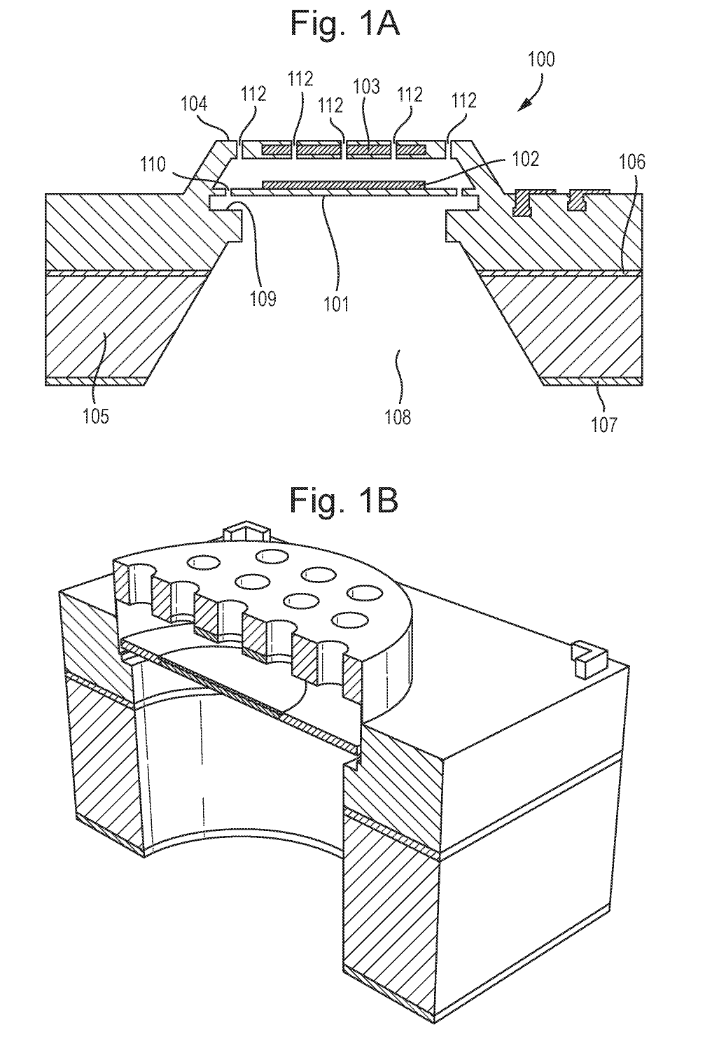

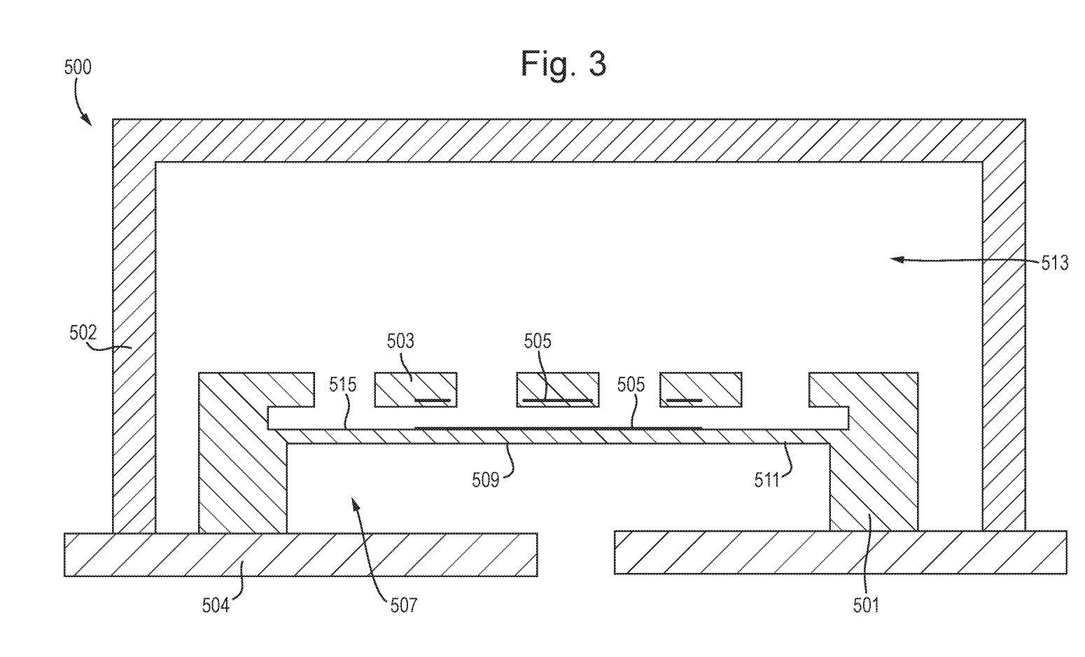

FIG. 3 shows a schematic of an example of a MEMS device 500, including a MEMS transducer 501, configured to operate as a microphone. The MEMS device 500 also includes a package 502 (the package comprising a substrate 504), and may also be referred to as a packaged MEMS transducer. In this example, as in the existing system shown in FIGS. 1A and 1B, the MEMS transducer 501 includes a back-plate 503 and uses a capacitive readout system (not illustrated). Each of the back-plate 503 and the flexible membrane 511 includes an electrode 505. Variations in the separation between the fixed back-plate 503 and the flexible membrane 511 are detected by monitoring the capacitance between the electrodes 505, as discussed above.

The example shown in FIG. 3 differs from the existing system shown in FIGS. 1A and 1B at least because the front volume 507 (that is, the volume through which incident sound waves reach the first surface 509 of the membrane 511) is fluidically isolated from the back volume 513 (that is, the volume having a boundary partially defined by the second surface 515 of the flexible membrane 511). The term “fluidically isolated” means that there is substantially no fluid communication (and preferably no fluid communication at all) between the first side of the flexible membrane 511 and the second side of the flexible membrane 511, either through the membrane 511 or around the membrane 511. As such, there are no bleed holes, i.e. pressure equalisation holes, between the front volume 507 and back volume 513, and no flow paths (including flow paths having high acoustic impedance) through the membrane 511. As the membrane 511 does not contain substantially any perforations, it can be referred to as an unperforated membrane. The term “fluid” is used here and throughout to refer to both liquid and gaseous substances.

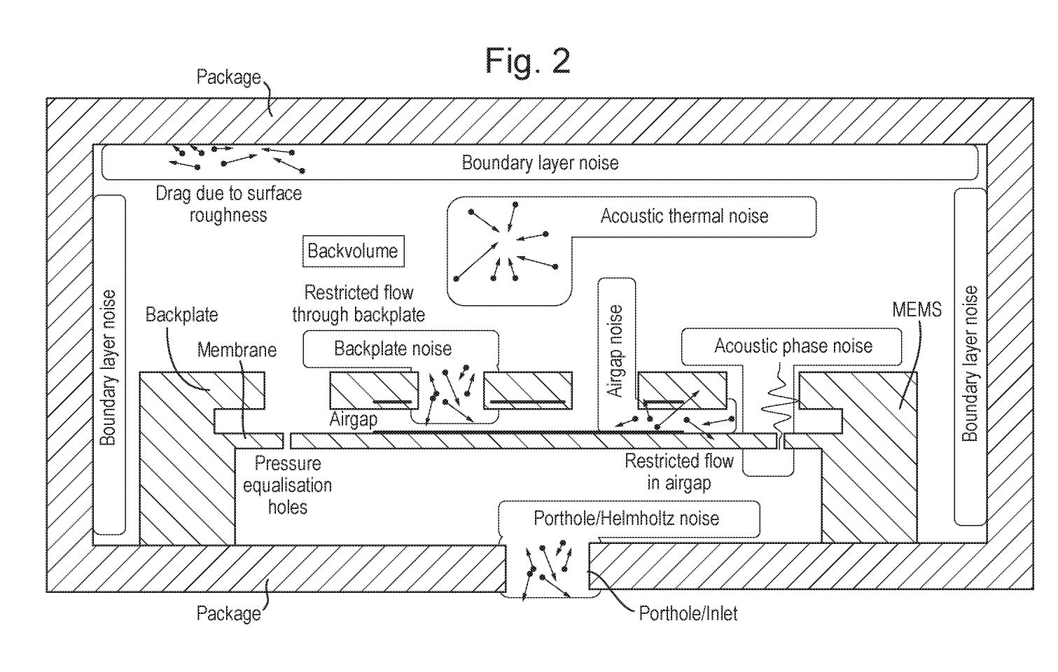

The negligible (or preferably absence of) fluid communication between the front volume 507 and the back volume 513 allows one of the sources of noise discussed above with reference to FIG. 2 to be removed. In order to fluidically isolate the first surface 509 of the flexible membrane 511 from the second surface 515 of the flexible membrane 511, there are no pressure equalisation holes (that is, bleed holes) between the front volume 507 and the back volume 513, therefore there is no transfer of air though these bleed holes and the acoustic phase noise previously generated by these holes can no longer reduce the SNR.

Accordingly, the example of a MEMS device 500 shown in FIG. 3 may provide an improvement in the SNR (by reducing the noise) relative to existing systems.

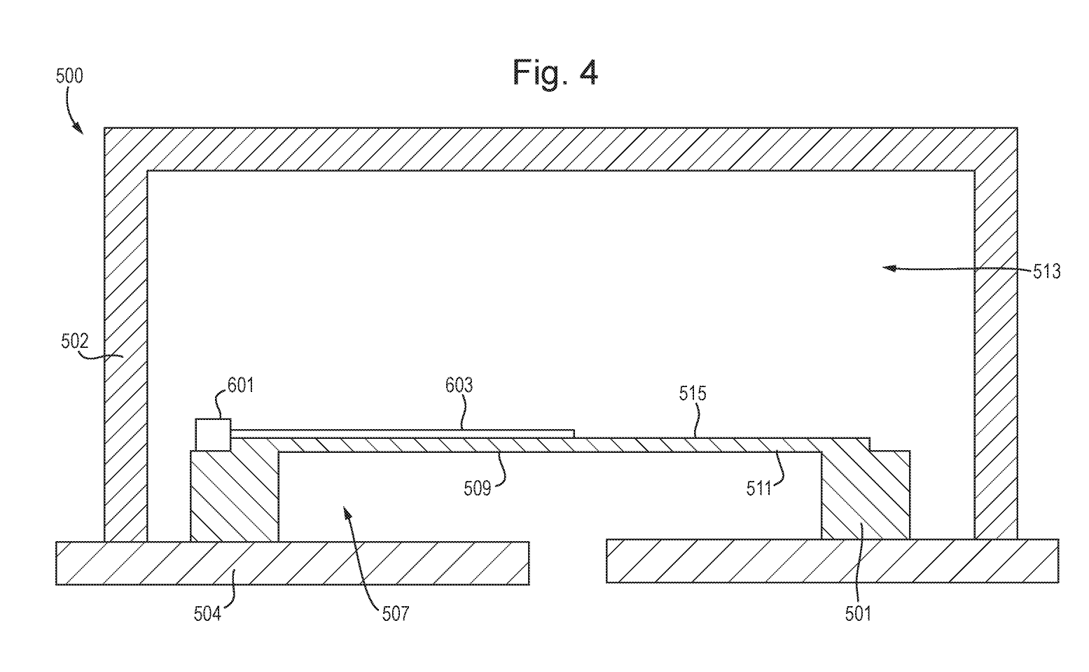

A further example is shown in FIG. 4. FIG. 4 illustrates how the SNR can potentially be improved by removing additional sources of noise from within an MEMS device. In the example shown in FIG. 4, the MEMS transducer 501 does not include a back-plate structure. The absence of the back-plate mitigates the generation of noise due to the passage of air molecules through acoustic holes in the back-plate (back plate noise), and also alleviates the generation of noise due to the movement of air molecules in the gap between the back-plate and the membrane (air gap noise).

The movement of air molecules through and around the back-plate can be a significant source of noise for MEMS transducers configured to operate as microphones, therefore the absence of the back-plate can greatly improve the SNR. However, capacitive microphones operate by measuring the capacitance between a pair of electrodes, one of said electrodes being mounted on the back-plate. As such, the removal of the back-plate necessitates a different sensing mechanism to capacitive sensing. In the example shown in FIG. 4, an optical sensing system is employed.

Accordingly, FIG. 4 shows an example of a MEMS device configured to operate as an optical microphone. Alternative sensing systems, such as piezoelectric sensing systems, can also be used. Piezoelectric systems lack the advantages provided by optical sensing systems, as discussed below.

Optical transducers, in particular optical microphones, are described in United Kingdom Patent Application No. 1705492.5 filed by the present Applicant.

As explained more fully in United Kingdom Patent Application No. 1705492.5, optical microphones do not require capacitive sensing systems, and accordingly can advantageously be implemented without the use of back-plates. In optical microphone systems such as the example shown in FIG. 4, an electromagnetic wave emitter 601, such as a Light Emitting Diode (LED) or a semiconductor laser, is used to generate electromagnetic radiation. Typically, although not exclusively, electromagnetic radiation in the visible region of the electromagnetic spectrum is generated.

The generated electromagnetic radiation is then carried by an electromagnetic waveguide 603, which moves with the flexible membrane 511. The electromagnetic waveguide 603 may be formed integrally with the flexible membrane 511, that is, the electromagnetic waveguide 603 and flexible membrane 511 may be formed from substantially the same material as a single piece. The electromagnetic waveguide 603 is configured to constrain the propagation of electromagnetic waves of a given wavelength range (the electromagnetic wave emitter 601 is selected to generate electromagnetic radiation in the applicable wavelength range). The electromagnetic waveguide 603 may, for example, be a rib-type waveguide and protrude from a surface of the flexible membrane 511 (as shown in FIG. 4), or may be a gradiated refractive index-type waveguide which constrains electromagnetic radiation using variations in the refractive index of a material and may be formed within the membrane 511.

The operation of the optical microphone is based on the principle that the movement of the flexible membrane (comprising the electromagnetic waveguide) due to incident sound waves alters the properties of electromagnetic waves within the electromagnetic waveguide. This alteration can be detected using an electromagnetic detector (not shown), such as a photodiode or photomultiplier tube, and used to deduce the properties of the incident sound wave.

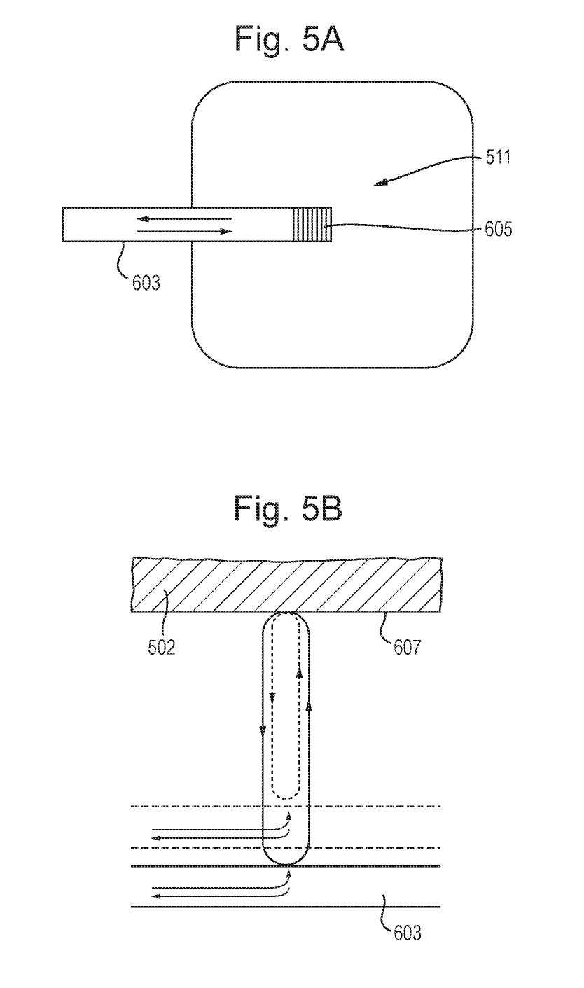

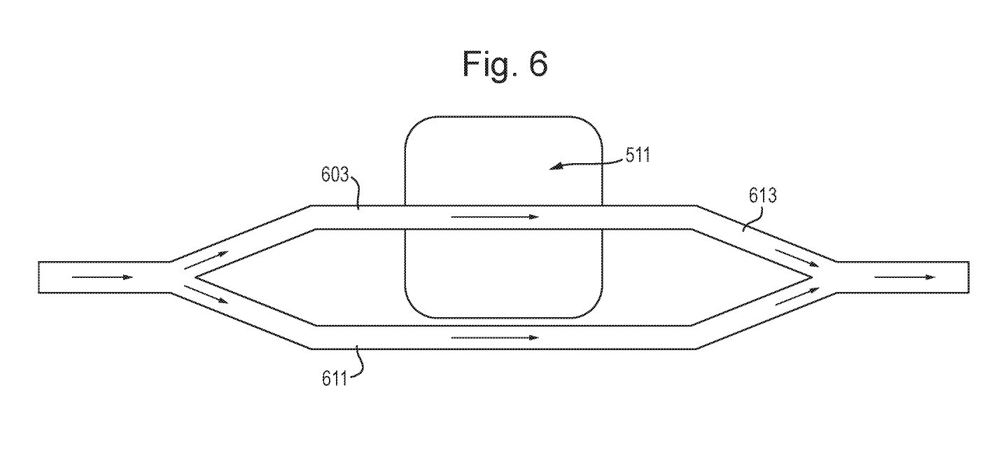

Various different configurations can be used to effect optical microphone systems, and different properties of the electromagnetic radiation can be monitored by the electromagnetic detector. The electromagnetic detector may be configured to monitor the intensity of the detected electromagnetic radiation, the phase of the detected electromagnetic radiation, and so on. MEMS optical microphone systems can be divided into systems which deflect the electromagnetic radiation out of the plane of the flexible membrane, and those which do not. FIG. 5 shows an example of a flexible membrane 511 and electromagnetic waveguide 603 of an optical microphone system which deflects the electromagnetic radiation out of the plane of the flexible membrane, and FIG. 6 shows an example of a system which does not deflect the electromagnetic radiation out of the plane of the membrane 511.

In the example shown in FIG. 5A, a flexible membrane 511 and electromagnetic waveguide 603 terminating in an electromagnetic wave diverter 605 for use in an optical microphone are shown. The operating principle is shown in FIG. 5B. This example utilises a configuration similar to that of a Fabry-Pérot interferometer. In this example, the light that has propagated along the electromagnetic waveguide 603 is diverted by an electromagnetic wave diverter 605 such as a diffraction grating, such that the electromagnetic wave is emitted from the waveguide 603. In this example, the electromagnetic wave diverter 605 is configured to divert the electromagnetic waves through an angle of approximately 90°, such that waves which were previously propagating through the waveguide 603 approximately parallel to a first surface of the flexible membrane 511 (and along a primary axis of the waveguide 603) are coupled out of the waveguide 603, and are thus diverted to propagate at an angle normal to the first surface of the membrane 511 at the point of emission.

Any suitable component can be used as the electromagnetic wave diverter, such as a grating or a membrane reflective surface at a particular angle with respect to a plane of the flexible membrane. Where the electromagnetic waves are to be diverted through an angle of approximately 90°, the membrane reflective surface is positioned at an angle of 45°. Gratings essentially require a series of precisely spaced grooves to be formed in a surface of the electromagnetic waveguide, and can therefore be formed without requiring any additional components to be incorporated into the system and to any required specifications. The grating can also act to allow electromagnetic waves to re-enter the electromagnetic waveguide if necessary. Use of a membrane reflective surface allows the diverted electromagnetic waves to be directed precisely as required (dependent on the angle of the membrane reflective surface with respect to the direction of propagation of the electromagnetic waves).

As shown in FIG. 5B, the diverted wave travelling away from the planar surface of the flexible membrane is then incident on a reflector 607 that is reflective to the wavelength range of the electromagnetic wave. The reflective surface of the reflector 607 of this example is substantially parallel to the plane of the flexible membrane 511, and is further configured to reflect the electromagnetic wave that has been diverted by the diverter back towards the flexible membrane 511. Where a reflector is used, this can be located in any position that allows light to be reflected back towards the flexible membrane. Examples of suitable locations for a reflector can be found in the package of a MEMS optical microphone device, including a substrate of a MEMS optical microphone device, or a lid of a MEMS optical microphone device. In the example shown in FIG. 5, the lid has been used. Configurations of the reflector are discussed in greater detail below, with reference to the general structure of the MEMS device.

The reflected electromagnetic wave then re-enters the waveguide. In the present embodiment, the reflected electromagnetic wave re-enters the same waveguide 603 as the electromagnetic wave was diverted out of by the diverter 605. The re-entry of the electromagnetic wave into the waveguide 603 is facilitated by the diverter 605, which is configured to again divert the electromagnetic waves through an angle of approximately 90°, such that electromagnetic waves are once again travelling substantially parallel to the planar surface of the flexible membrane and propagating along the electromagnetic waveguide. However, in alternative configurations, the reflector reflective surface may be configured to reflect the electromagnetic waves at a further waveguide (where the entry of the electromagnetic wave into the waveguide can be facilitated by a further diverter), or may be configured to reflect the electromagnetic wave directly at an electromagnetic wave detector. Where the reflected electromagnetic waves subsequently re-enter the electromagnetic waveguide, this reduces the number of required components, thereby simplifying the formation of the system.

The electromagnetic waves then exit the electromagnetic waveguide 603 and encounter an electromagnetic wave detector (not illustrated), at which the wave is detected. The operating principle this example is illustrated by FIG. 5B. In FIG. 5B, the position of the electromagnetic waveguide 603 and the path of the electromagnetic wave when the flexible membrane 511 is in an undisturbed position is indicated by solid lines, and the position of the electromagnetic waveguide 603 and the path of the electromagnetic wave when the flexible membrane 511 has moved is indicated by the dashed lines.

In this example, the movement of the flexible membrane (and the corresponding movement of the electromagnetic waveguide) causes the separation between the point of emission of the electromagnetic waves from the waveguide and the reflective surface of the reflector to vary. The electromagnetic waves are monochromatic, and are emitted at a given phase. The system is configured such that the separation between the point of emission of the electromagnetic waves and the reflective surface (multiplied by two, as the wave must travel both ways) results in a known shift in the phase of the electromagnetic wave. This phase shift is monitored at the electromagnetic wave detector, allowing the position of the membrane (and hence the properties of incident sound waves) to be deduced.

As discussed above, the example shown in FIG. 5 relies on the deflection of the electromagnetic wave out of the plane of the membrane. FIG. 6 illustrates the principle of a further example, which does not rely on the deflection of the electromagnetic wave out of the plane of the membrane. This example uses a configuration which is similar in some respects to a Mach-Zehnder interferometer.

The configuration of the example illustrated by FIG. 6 utilises a beam splitter (not shown) to split monochromatic electromagnetic radiation emitted from an electromagnetic wave emitter into two portions. Any suitable beam splitting device can be used; the illustrated example uses a half silvered mirror. The two portions pass down two separate paths formed by one or more electromagnetic waveguides, before recombining at a recombination point. The first of these paths is a reference path 611, which passes from the beam splitter to the recombination point without passing over the flexible membrane 511. The second path is a sample path 613 that passes over the flexible membrane 511 to reach the recombination point.

When the flexible membrane is in an undisturbed position, the lengths of the sample path 613 and the reference path 611 (between the beam splitter and the recombination point) are equal. Prior to splitting, the monochromatic electromagnetic radiation has a single phase. If the lengths of the sample path 613 and the reference path 611 remain the same (because the flexible membrane 511 does not move as the electromagnetic radiation passes down the sample path 613 and reference path 611), then the electromagnetic radiation sent down the sample path 613 and the electromagnetic radiation sent down the reference path 611 remain in phase with one another. By contrast, if the flexible membrane 511 is moved from the undisturbed position while the electromagnetic radiation travels down the paths (due to incident sound waves), this alters the length of the sample path 613 relative to an undisturbed position. Accordingly, the electromagnetic wave that passes along the sample path 613 undergoes a phase shift relative to the electromagnetic wave that passes along the reference path 611, such that the two waves are no longer perfectly in phase with one another.

The electromagnetic waves recombine at the recombination point. If the electromagnetic wave that passed along the sample path 613 has undergone a phase shift relative to the electromagnetic wave that passed along the reference path 611, the recombined waves will generate an interference pattern. Measurements of interference patterns resulting from the interaction of the wave from the reference path 611 and the wave from the sample path 613 allow a degree of phase shift to be detected, which in turn allows the deflection of the flexible membrane 511 to be obtained.

As mentioned above, the removal of the back-plate substantially removes several noise sources and thereby can significantly improve the SNR of the MEMS microphone system. The use of optical sensing techniques in the MEMS device is also well suited to configurations wherein there is no fluid communication between the first and second sides of the flexible membrane. This is the case because the sensitivity of optical sensing techniques is typically higher than that of capacitive sensing techniques, and optical sensing techniques can compensate for existing membrane deflections more effectively than capacitive sensing techniques, as discussed in detail below.

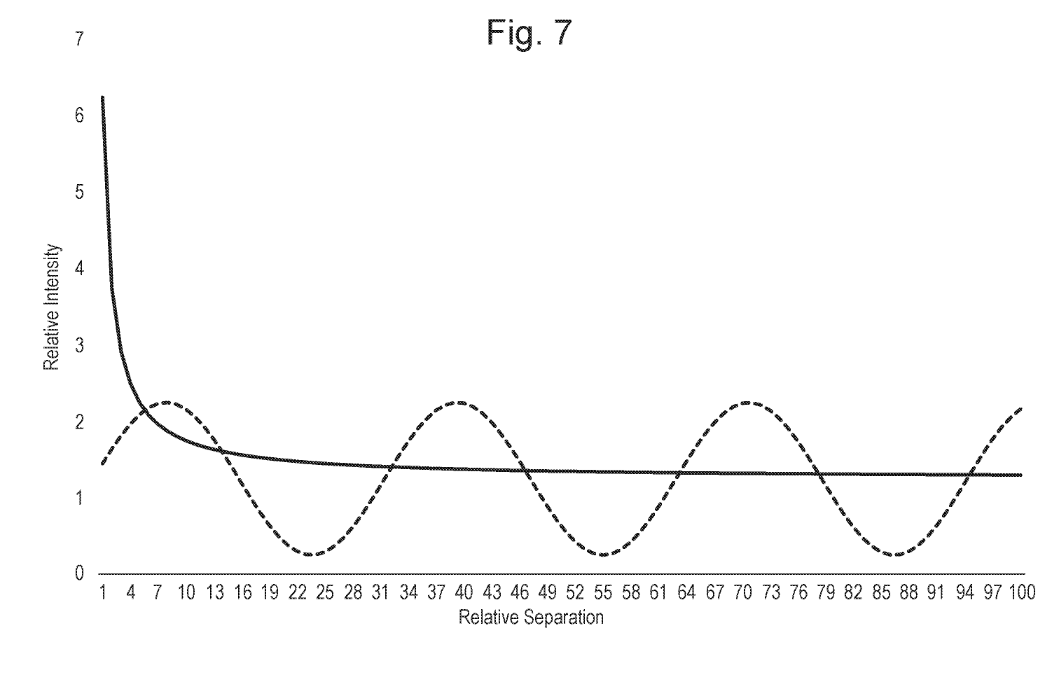

Capacitive sensing techniques operate by detecting variations in the capacitance between two electrodes. The capacitance between the two electrodes varies proportionally with the reciprocal of the separation between the electrodes, on a constant curve. When using optical techniques, the variation in the measured properties of the electromagnetic radiation (such as the intensity or phase shift) varies periodically (that is, cyclically) with constantly changing separation. An example outline plot of the variation in intensity with membrane deflection for capacitive and optical sensing systems is shown in FIG. 7. In FIG. 7, the Y axis shows relative intensity in arbitrary units, while the X axis shows relative separation in arbitrary units. The variation in recorded intensity with separation for the optical system is illustrated by the dashed line, while the variation in recorded intensity with separation for the capacitive system is illustrated by the solid line. Increasing membrane deflection provides increasing relative separation. For the capacitive system, the separation is between the two electrodes, while for the optical system the separation is between the point at which electromagnetic radiation is emitted from the waveguide on the flexible membrane and a reflector.

The sensitivity exhibited by optical systems can be higher than that of capacitive systems, because the determining factor of the sensitivity is the wavelength of the electromagnetic radiation used in the system. The plot in FIG. 7 illustrates that optical sensing techniques also generally allow a constant displacement in the membrane (prior to any incident sound waves) to be taken into account more easily. This can best be understood with reference to an incident sound wave causing a deflection of 5 arbitrary units in the membrane. With reference to the plot in FIG. 7, if the membrane of the capacitive system is not deflected at the time the sound wave is incident (so is at position 0), the deflection of 5 arbitrary units will take the membrane from 0 to 5 on the relative separation scale, resulting in a large and easily detectable variation in the relative intensity (capacitance). However, if the flexible membrane is already subject to a significant deflection (towards the right of the plot, for example a deflection equivalent to a separation of 70 in the arbitrary units) prior to the deflection due to the incident sound waves (for example, due to a pressure differential across the flexible membrane, as discussed below), then the deflection of 5 arbitrary units will take the membrane from 70 to 75 on the relative separation scale. As shown by FIG. 7, this will result in a small variation in the relative intensity (capacitance). Therefore the accuracy of detection may be reduced if a capacitive system is used with a membrane subject to a significant deflection prior to any incident sound waves; this reduced sensitivity can make it difficult to compensate for deflection in the membrane.

For an optical sensing system, the variation in the intensity of detected light upon the incidence of a given sound wave would be similar or the same regardless of whether the membrane was already under a significant deflection. With reference to FIG. 7, if the flexible membrane in the optical system was deflected by an incident sound wave from 70 to 75 on the relative separation axis, the change in relative intensity would be relatively significant; approximately equal to that for a change from 0 to 5. This is due to the cyclic variation in intensity with separation of the optical system, as discussed above. Therefore, optical systems exhibit higher and more consistent sensitivity across a broad range of relative separations, and are particularly suited to use with membranes subject to deflections other than those caused by incident sound waves and/or wherein the expected flexible membrane deflections with incident sound waves are of a small amplitude. The deflection of the membrane and reduction in the amplitude of deflection due to incident sound waves can both be influenced by the fluidic isolation of the first membrane surface from the second membrane surface, or the absence of fluid communication between the chamber and a region outside the chamber.

As discussed above, the fluidic isolation of the first membrane surface from the second membrane surface can result in a chamber of the MEMS device (which may be the back volume of a microphone) being fluidically isolated from a region outside the chamber. Typically, the region outside the chamber is the atmosphere surrounding the MEMS device, and the first membrane surface (and front volume) are in fluid communication with the surrounding atmosphere (and the chamber can therefore be described as substantially sealed). The front volume is typically in fluid communication with the atmosphere to allow sound waves to reach the flexible membrane by passing through the front volume. However, it can easily be envisaged that the region outside the chamber could be the interior of an airtight device in which the MEMS device is located, such that the region outside the chamber cannot be equated to the surrounding atmosphere.

The fluidic isolation of the chamber from the region outside the chamber results from the use of an unperforated flexible membrane and the absence of any bleed holes (for pressure equalisation). This allows noise sources related to the passage of air through the bleed holes/membrane perforations to be minimised. Further noise sources can be reduced by eliminating the back-plate and using a sensing mechanism not reliant on a back-plate, such as an optical sensing mechanism, as discussed above. However, and with reference to FIG. 2, boundary layer noise and acoustic thermal noise can also generate noise and thereby reduce the SNR.

Boundary layer noise arises from collisions of air molecules with the surrounding surfaces of the MEMS device, and acoustic thermal noise arises from collisions of air molecules with one another. The amount of noise generated by both boundary layer noise and acoustic thermal noise is proportional to the kinetic energy of the air molecules involved in the collisions (that is, collisions with the surrounding surfaces and each other respectively), which in turn is proportional to the mass of the molecules involved. Accordingly, the amount of noise generated by both boundary layer noise and acoustic thermal noise can be reduced by replacing the air in the sealed chamber with a different gas, having a lower molecular weight than air. In this way, for a given temperature, the kinetic energy of the different gas molecules will be less than that of air molecules at the same given temperature, and the noise level will be reduced.

The lightest element, hydrogen, may not be suitable for all applications of a MEMS device due to its flammability. Accordingly, helium may be selected as a suitable gas to fill the back volume. Other gases that are lighter than air, such as neon, could also be used. The mean molecular weight of helium is 4 grams per mole (the atomic weight of helium is 4), while air is primarily composed of nitrogen and oxygen and has a mean molecular weight in the region of 28.97 grams per mole. Accordingly, filling the back volume with helium instead of air can significantly reduce the total kinetic energy of the molecules in the back volume, thereby reducing boundary layer noise and acoustic thermal noise.

In addition to or alternatively to reducing the mean molecular weight of the gas in the chamber, the total kinetic energy (and hence boundary layer noise and acoustic thermal noise) may be reduced by reducing the amount of fluid, e.g. gas, in the chamber. This is equivalent to reducing the pressure in the chamber, all other conditions such as the temperature of the gas and the volume of the chamber being equal. Reducing the amount of gas in the chamber reduces the frequency of collisions between the gas molecules and between gas molecules and the surrounding structures. Accordingly the constant amount of gas in the chamber may be set such that, at standard temperature and pressure (approximately 273 K and 1.01×10⁵ kgm⁻¹ s⁻², that is, 0° C. and 101 kPa) the gas in the chamber is at a lower pressure than the pressure in the region outside the chamber.

In order to minimise boundary layer noise and acoustic thermal noise as far as possible, the chamber may be a vacuum (that is, the constant amount of gas in the chamber is zero gas). However, while fully evacuating the chamber to create a vacuum would provide the lowest possible levels of boundary layer noise and acoustic thermal noise, the pressure differential between the chamber and the region outside the chamber may put undue stress on the components forming the chamber, particularly the flexible membrane. Although the stress can be mitigated to some extent by using a flexible membrane form that distributes the stress evenly, such as a circular membrane (wherein the first and second surfaces of the flexible membrane are circular, as discussed below), a vacuum is rarely used. A more typical pressure level for the chamber, when the device is at standard temperature and pressure, is approximately 1 kgm⁻¹ s⁻², that is, 1 Pa. Assuming that the region surrounding the chamber is at normal atmospheric pressure of 1.01×10⁵ kgm⁻¹ s⁻², this chamber pressure level significantly reduces the boundary layer noise and acoustic thermal noise relative to maintaining the chamber at the same pressure as the surrounding atmosphere.

In order to mitigate the effects of a pressure differential between the chamber and the region surrounding the chamber, it can be helpful if the flexible membrane is formed in such a way as to increase the rigidity of the membrane relative to known flexible membrane structures. This may be achieved by forming the membrane layer so as to have a domed structure, even when there is no pressure differential across the membrane (at equilibrium pressure conditions).

The domed or inherently curved shape of the membrane layer, even at substantially equilibrium pressure conditions and without any load on the membrane layer, gives rise to a number of advantages. In particular, it will be appreciated that the domed shape of the membrane imparts structural and/or geometrical strength to the membrane structure. Thus, the membrane is inherently stronger and/or stiffer than a flat or planar membrane having the same dimensions. This increased strength of the membrane may be beneficially utilised in a number of applications and MEMS transducer designs. For example, as a consequence of the increased strength it is possible to provide a MEMS transducer membrane having a reduced thickness as compared to planar membrane designs without any detriment to the robustness of the membrane. Furthermore, a number of transducer designs e.g. transducer designs having a relatively small back volume—may require or at least benefit from a stronger membrane in order to manage the risk of membrane damage or failure. This can be achieved, according to examples described herein, by the provision of membrane having a curved surface region and, preferably, without the need to thicken the membrane which may reduce flexibility of the membrane and, thus, the sensitivity of the transducer. Further details of the dome structure, and the advantages thereof, can be found in greater detail in co-pending application P3293 being filed concurrently by the present Applicant.

To provide protection the MEMS transducer will typically be contained within a package (forming a packaged MEMS transducer). The package effectively encloses the MEMS transducer and can provide environmental protection and may also provide shielding for electromagnetic interference (EMI) or the like. The package also provides at least one external connection for outputting the electrical signal to downstream circuitry. For microphones and the like the package will typically have a sound port to allow transmission of sound waves to/from the transducer within the package.

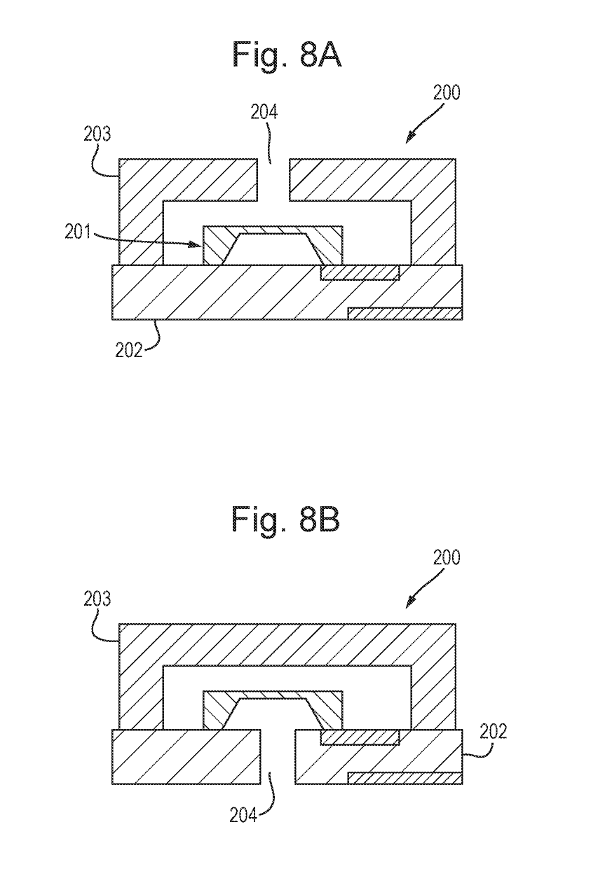

Various package designs are known. For example, FIGS. 8A and 8B illustrate packaged MEMS transducers 200, comprising “lid-type” packages. A MEMS transducer 201 is mounted to an upper surface of a package substrate 202. The package substrate 202 may be PCB (printed circuit board) or any other suitable material. A cover or “lid” 203 is located over the transducer 201 and is attached to the upper surface of the package substrate 202. The cover 203 may be a metallic lid, a plastic lid, and so on. In FIG. 8A, an aperture 204 in the cover 203 provides a sound port and allows acoustic signals to enter the package. In FIG. 8B, the packaged MEMS transducer 200 is configured such that an aperture 204 in the substrate 202 provides the sound port and the MEMS transducer 201 is mounted such that the flexible membrane of the transducer extends over the sound port. In FIG. 8B, there is no aperture in the lid 203.

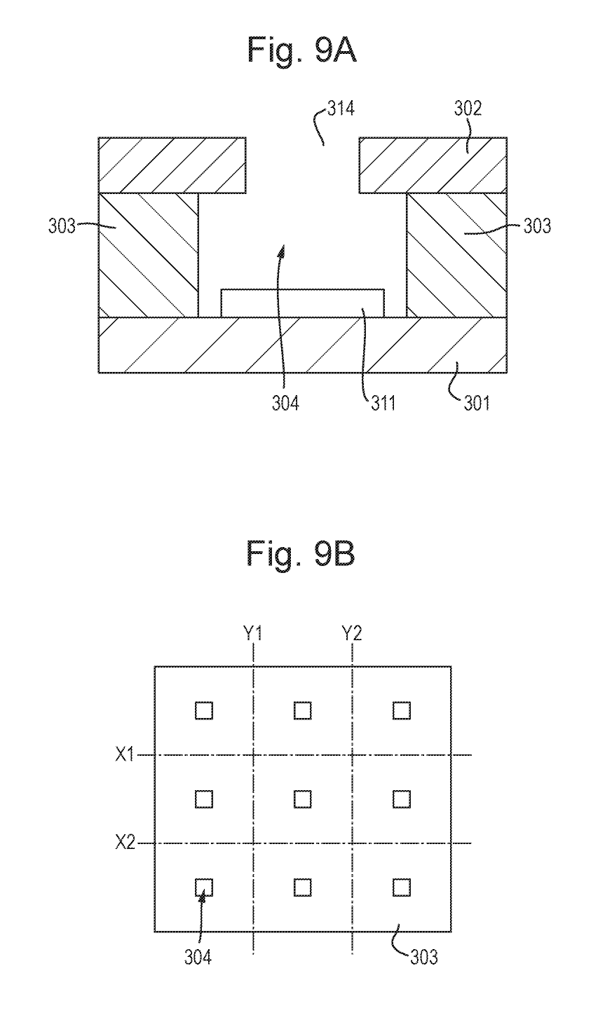

FIG. 9A shows a schematic cross section of an example of a packaged MEMS transducer (MEMS device) comprising an alternative package type known as a “laminate” type package that comprises operatively constructed and connected printed circuit boards, such as FR-4, that are mechanically and electrically connected together, using techniques that are well known to those skilled in the art. In the example package shown in FIG. 9A, there are a first member 301 comprising a FR-4 board core having metalized tracks, pads, bonds and a solder mask stop layer for example operatively applied to the upper and lower surfaces thereof, a second member 302 disposed in a plane overlying the first member and comprising an FR-4 board coated on an inner/lower surface thereof with metalized tracks, pads and a solder stop layer, and a third member 303 (or “interposer member”) which is interposed between the first and second members. The third member forms at least a part of the side walls of the package. The third member can be considered to comprise a cavity or void such that, when the three members are bonded together e.g. by means of solder pads, bonds and through vias, a space 304 is formed between the lower surface of the second member 302 and an upper surface of the first member 301, wherein the side walls of the space are partially provided by the cavity edges of the third member 303. A MEMS transducer 311 and an integrated circuit may be provided within the space 304, i.e. the cavity or void.

Although several different arrangements are known, in the example shown in FIG. 9A an acoustic port hole 314 extends through the second member 302 of the package. The use of laminate type packaging provides advantages relative to lid type packaging, particularly associated with the mass production of MEMS devices.

As those skilled in the art will be aware, MEMS transducer die, are typically produced in large wafers, with each wafer often being used to form several thousand MEMS die. With lid type packaging, it is generally necessary after one, or possibly more, MEMS die has been attached to the package substrate (usually FR4), to attach a lid individually over each MEMS transducer die to form each packaged MEMS transducer, i.e. MEMS device. By contrast, the triple layer structure of the laminate packaging allows all of the MEMS devices to be constructed using combined processes (for example, sealing the interposed layer 303 between the first layer 301 and second layer 302), before the panel is divided into individual MEMS devices.

FIG. 9B shows a schematic plan view of a third layer 303 prior to construction of the triple layer structure and division into individual MEMS devices. The spaces 304 are shown in the third layer 303; there is typically one space per MEMS device although a single MEMS device may comprise plural spaces. After the layer structure has been prepared, by the attachment of the first and second layers on either side of the third layer, the layer structure may be divided into the individual MEMS devices (for example, along lines X1, X2, Y1 and Y2 as shown in FIG. 9B). Using a larger number of combined processes to form the MEMS devices in this way significantly reduces the time and expense relative to the use of lid type packaging; this is commonly referred to as parallel processing.

A MEMS device comprising a MEMS transducer configured to act as a microphone will typically comprise a package, which acts to contain the MEMS transducer and may provide shielding (both physical shielding and electromagnetic shielding) as discussed above. In some examples, the structure of the package may also define part of the boundary of the chamber, to fluidically isolate the first membrane surface from the second membrane surface. Various types of package may be used; examples include lid-type packages and laminate packages. In examples including a backplate (which may be required for capacitive sensing systems), the chamber may be defined by the MEMS substrate alone, such that the chamber is between the flexible membrane and the backplate.

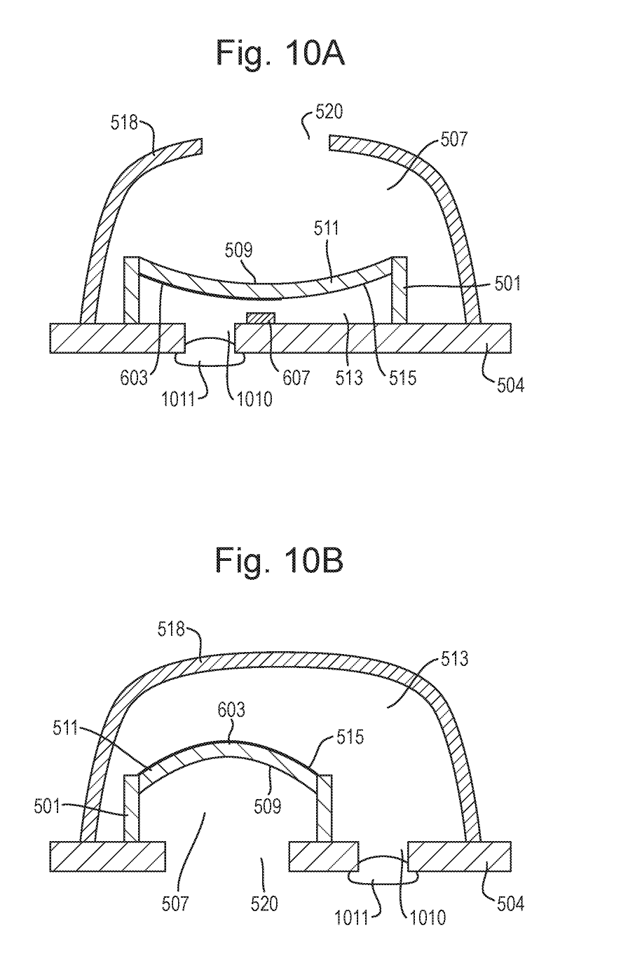

FIG. 10A and FIG. 10B show two examples of MEMS transducers 501 configured to operate as microphones, wherein the MEMS devices including the MEMS transducers also comprise lid-type packages. FIG. 10A shows a configuration wherein a sound port 520 in the lid 518 of the package allows sound waves to reach the first surface 509 of the flexible membrane 511, via the front volume 507. FIG. 10B shows a configuration wherein a sound port 520 in the substrate 504 allows sound waves to reach the first surface 509 of the flexible membrane 511.

In FIG. 10A, the back volume 513 (the chamber partially bounded by the second surface 515 of the flexible membrane 511) is defined by the flexible membrane 511 and a substrate 504 of the MEMS device. In this example the back volume 513 is at a lower pressure than the region outside the back volume (when the MEMS device is at standard temperature and pressure, STP). As a result of this lower pressure, there is a pressure differential across the flexible membrane 511. The result of this pressure differential is the deformation of the flexible membrane 511 shown in FIG. 10A, wherein the membrane 511 bows into the back volume 513. The MEMS device shown in FIG. 10A also includes an optical sensing system, comprising an electromagnetic wave guide 603 and, in this example, a separate reflector 607. An alternative sensing mechanism (such as an alternative optical sensing system not requiring a reflector) could also be used.

The sound port 520 in the example shown in FIG. 10A is positioned such that the opening of the sound port 520 is substantially parallel to the first surface 509 of the flexible membrane 511 (that is, the centre of the sound port 520 opening is directly above the flexible membrane). Although this positional relationship is not essential, this provides an efficient path through the front volume 507 for sound waves to reach the first surface 509 from outside the MEMS device. The location of the sound port 520 in the lid 518 means that the logical location for the reflector 607 is on the substrate 504, inside the back volume 513, as shown in FIG. 10A. Again, other reflector locations could also be used.

FIG. 10B shows an alternative example, wherein the sound port 520 is located in the substrate 504, rather than the lid 518. As discussed above, the first surface 509 of the flexible membrane 511 is defined as the surface upon which sound waves are incident (the sound waves having passed through the front volume 507). Accordingly, the positions of the first and second surfaces of the flexible membrane relative to the substrate 504 and the lid 518 are reversed in the MEMS device shown in FIG. 10B. Also, in the example shown in FIG. 10B, the chamber (back volume 513) is partially defined by the lid 518 of the package.

In the example of FIG. 10B, the back volume 513 is again at a lower pressure than the region outside the back volume (when the MEMS device is at standard temperature and pressure, STP), for example, approximately 1 kgm⁻¹ s⁻². As a result of this lower pressure, there is a pressure differential across the flexible membrane 511. The result of this pressure differential is the deformation of the flexible membrane 511 shown in FIG. 10B, wherein the membrane 511 bows into the back volume 513. A different optical sensing system to that shown in FIG. 10A is used in the example of FIG. 10B, specifically a system similar to that shown in FIG. 6 and not requiring a reflector. However, if the FIG. 10B example were to use a reflector, this could be located on the inside surface of the lid, inside the back volume. Alternatively, the reflector could be located elsewhere, for example in the front volume (facing toward the first surface of the flexible membrane), supported on support struts.

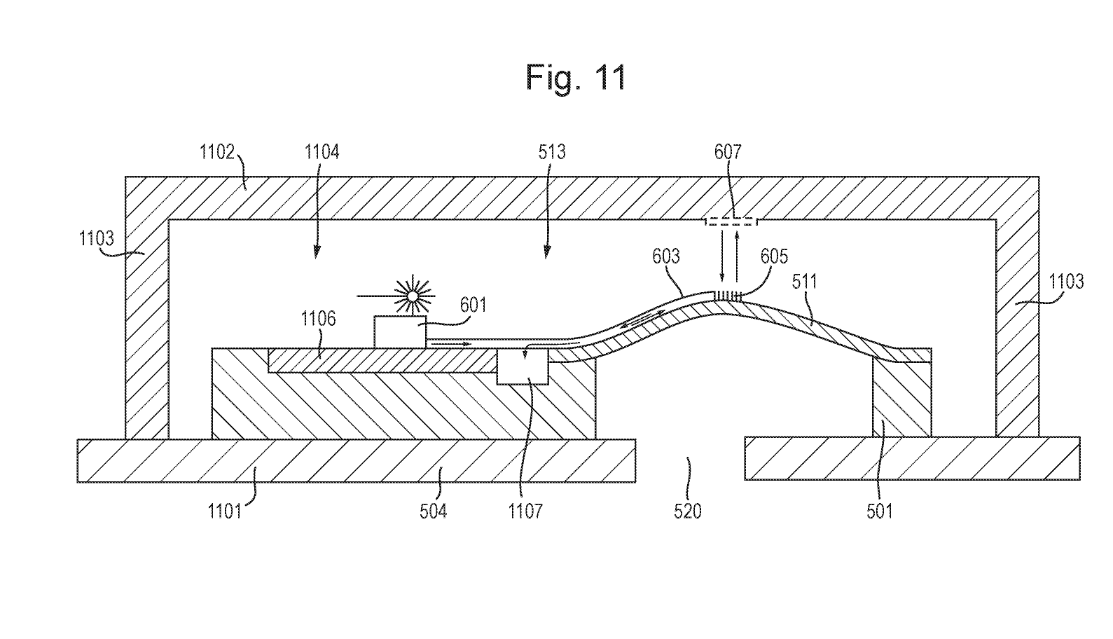

In the examples shown in FIGS. 10A and 10B, the MEMS devices comprise lid type packages. In FIG. 11, an example using a laminate package is shown. As explained above with reference to FIG. 3, the laminate packages include a first planar member 1101 and second planar member 1102 located either side of a third (interposed) member 1103. The third member 1103 comprises a cavity or space 1104, in which is located the MEMS transducer 501. The structures of the MEMS device shown in FIG. 11 is similar to those of the MEMS devices in FIGS. 10A and 10B, save that the sides and the “top” (the planar surface opposite the MEMS substrate) of the example shown in FIG. 11 are formed from the laminate layers, instead of the lid 518 of the examples shown in FIGS. 10A and 10B. Like the examples shown in FIGS. 10A and 10B, the back volume 513 of the example shown in FIG. 11 is maintained at a lower pressure than the region outside the back volume (when the MEMS device is at standard temperature and pressure, STP), for example, approximately 1 kgm⁻¹ s⁻². As a result of this lower pressure, there is a pressure differential across the flexible membrane 511. The result of this pressure differential is the deformation of the flexible membrane 511 shown in FIG. 11, wherein the membrane 511 bows into the back volume 513. In the examples shown in FIG. 11, the back volume 513 is also filled with a gas (at the lower pressure) having a lower mean molecular weight than air, such as neon or helium. Also similarly to the example shown in FIG. 10A, the example in FIG. 11 includes an optical sensing system using an electromagnetic waveguide 603, an electromagnetic wave emitter 601 (an LED in this example), a diffraction grating 605, a reflector 607 separate from the flexible membrane 511, and an electromagnetic wave detector 1107. The laminate structure may use different sensing systems (including capacitive systems or other optical systems), pressures and/or gas compositions. Also the sound port may be located “above” the membrane (in the second layer 1102), analogously to the structure shown in FIG. 10A.

The use of laminate packaging provides advantages relative to lid type packaging, particularly associated with the mass production of MEMS devices. As those skilled in the art will be aware, MEMS devices are typically produced using large wafers, with each wafer often being used to form several thousand MEMS devices (as discussed in detail above. With lid type packaging, it is necessary to attach a lid individually (or in small numbers) over MEMS transducers to form each MEMS device. By contrast, the triple layer structure of the laminate packaging allows all of the MEMS devices to be constructed using a greater degree of parallel processing (for example, sealing the interposed layer between the first and second layers), before the resulting panel is divided into individual MEMS devices. Using parallel processing to form the MEMS devices in this way significantly reduces the time and expense relative to the use of lid type packaging. Accordingly, while each of the two types of packaging may be particularly well suited to some specific MEMS device applications, for general applications without particularly stringent packaging requirements laminate packaging is typically preferred.

In all of the examples discussed above, a flexible membrane is a key part of the sensing apparatus. The flexible membrane is formed as part of a larger membrane layer, and the shape of the flexible membrane is determined by the shape of the connection between the membrane layer and the rest of the MEMS transducer. The flexible membrane can be formed such that the first and second surfaces of the flexible membrane have any shape, determined by the particular requirements of a given MEMS transducer in a MEMS device configured to operate as a microphone. For example, first and second surfaces having a square shape may be used, in order to maximise the sensing surface area relative to the total area occupied by the MEMS device. However, for applications wherein the chamber is maintained at a lower pressure than a region outside the chamber, a flexible membrane having circular first and second surfaces is often used. This is because the lower pressure creates a pressure differential across the membrane, essentially applying a constant force to the membrane. Use of circular first and second surfaces more equally distributes the force across the flexible membrane, making the membrane less likely to tear or rupture. While the distribution of the force is not key when the difference in pressure in the chamber and a region outside the chamber is comparatively small, the distribution of the force can become increasingly important as the difference in pressure is increased. Therefore, particularly for examples wherein the back volume is a vacuum or near vacuum, a flexible membrane having circular first and second surfaces may be used.

MEMS devices to be used as microphones in accordance with the examples above may be formed using standard techniques, as the person skilled in the art will be aware of. The methods may be modified such that the front volume is fluidically isolated from the back volume (chamber). These modifications can include the omission of the formation of bleed holes or other means of fluid communication between the front volume and back volume.

For examples wherein the constant amount of gas in the back volume is set such that the back volume is at a lower pressure than the region (such as the front volume) outside the back volume when the MEMS device is at standard temperature and pressure, and/or wherein a gas other than air is located in the back volume, additional formation steps may be taken. FIGS. 10 and 11 illustrate two formation steps which may be used for lower pressure and/or non-air back volumes.

In the examples shown in FIG. 10, a gas transfer hole 1010 is provided in the substrate during the formation process. The gas transfer hole 1010 may be formed at the same time as a sound transfer port 520, if the substrate includes a sound transfer port 520, or may be formed at another time. This gas transfer hole 1010 provides fluid communication between the cavity which will become the chamber and the surrounding atmosphere during the formation process. Accordingly, the gas transfer hole 1010 may lead into the cavity under the package (that is, the lid as in FIG. 10B, or the space in the laminate package), or the cavity under the membrane (as in FIG. 10A). A blob of solder is located on the edge of the gas transfer hole 1010, so as to not block the gas transfer hole 1010.

In order to lower the pressure in the cavity which will become the chamber, the MEMS device being formed is placed in an environment (such as a clean room or oven) at the desired pressure and containing the desired gas composition. The cavity is then filled to the desired pressure and/or gas composition as the cavity equalises with the environment. Then, while still in the environment, the solder blob, or pip, is heated until the solder melts. The melted solder then enters the gas transfer hole via capillary action. The solder is then cooled, and solidifies to form a solder plug 1011 that seals the chamber, thereby preventing fluid communication between the back volume 513 and the region outside the back volume 513. The MEMS device may then be removed from the environment. The use of solder in this way can be referred to as solder pipping.

In the alternative formation method shown in FIG. 11, no gas transfer hole is required. Instead, the final layer forming the chamber (which may be the membrane or one of the first and second laminate layers, depending on the chamber location) is formed or fixed in an environment (such as a clean room or oven) at the desired pressure and containing the desired gas composition. The chamber is then sealed while containing the desired pressure/gas composition. This formation method is particularly well suited to use with laminate type packages, and is therefore favoured for mass production of MEMS devices as discussed above.

In the example shown in FIG. 11, a portion of the electronic circuitry 1106 (typically using a complementary metal-oxide semiconductor, CMOS) is located adjacent to the membrane, inside the package. However, the circuitry 1106 may also or alternatively be located such that the flexible membrane at least partially, and preferably fully, overlies the circuitry. That is, the circuitry is partially or (preferably) fully within a region defined by the second surface of the flexible membrane, when projected onto the plane of the circuitry. The portion of the electronic circuitry 1106 may be substantially all (or all) of the electronic circuitry of the MEMS device.

Configuration in which the flexible membrane partially or fully overlies a portion (possibly all) of the circuitry are particularly useful when the sound port is located in “above” the flexible membrane (that is, in the second layer 1102 of FIG. 11) rather than “below” the flexible membrane as is shown in FIG. 11. This is because, when the sound port is located in “above” the flexible membrane, there is additional free space “below” the flexible membrane for the circuitry. Configuring the MEMS device in this way allows the total size of the device to be reduced.

The flexible membrane may comprise a crystalline or polycrystalline material, such as one or more layers of silicon-nitride Si₃N₄.

MEMS transducers according to the present examples will typically be associated with circuitry for processing an electrical signal generated as a result of detected movement of the flexible membrane, either by a capacitive sensing technique or by an optical sensing technique. Thus, in order to process an electrical output signal from the microphone, the transducer die/device may have circuit regions that are integrally fabricated using standard CMOS processes on the transducer substrate.

The circuit regions may be fabricated in the CMOS silicon substrate using standard processing techniques such as ion implantation, photomasking, metal deposition and etching. The circuit regions may comprise any circuit operable to interface with a MEMS transducer and process associated signals. For example, one circuit region may be a pre-amplifier connected so as to amplify an output signal from the transducer. In addition another circuit region may be a charge-pump that is used to generate a bias, for example 12 volts, across the two electrodes. This has the effect that changes in the electrode separation (i.e. the capacitive plates of the microphone) change the MEMS microphone capacitance; assuming constant charge, the voltage across the electrodes is correspondingly changed. A pre-amplifier, preferably having high impedance, is used to detect such a change in voltage.

The circuit regions may optionally comprise an analogue-to-digital converter (ADC) to convert the output signal of the microphone or an output signal of the pre-amplifier into a corresponding digital signal, and optionally a digital signal processor to process or part-process such a digital signal. Furthermore, the circuit regions may also comprise a digital-to-analogue converter (DAC) and/or a transmitter/receiver suitable for wireless communication. However, it will be appreciated by one skilled in the art that many other circuit arrangements operable to interface with a MEMS transducer signal and/or associated signals, may be envisaged.

It will also be appreciated that, alternatively, the microphone device may be a hybrid device (for example whereby the electronic circuitry is totally located on a separate integrated circuit, or whereby the electronic circuitry is partly located on the same device as the microphone and partly located on a separate integrated circuit) or a monolithic device (for example whereby the electronic circuitry is fully integrated within the same integrated circuit as the microphone).

Examples described herein may be usefully implemented in a range of different material systems, however the examples described herein are particularly advantageous for MEMS transducers having membrane layers comprising silicon nitride.

It is noted that the example embodiments described above may be used in a range of devices, including, but not limited to: analogue microphones, digital microphones, pressure sensor or ultrasonic transducers. The example embodiments may also be used in a number of applications, including, but not limited to, consumer applications, medical applications, industrial applications and automotive applications. For example, typical consumer applications include portable audio players, laptops, mobile phones, PDAs and personal computers. Example embodiments may also be used in voice activated or voice controlled devices. Typical medical applications include hearing aids. Typical industrial applications include active noise cancellation. Typical automotive applications include hands-free sets, acoustic crash sensors and active noise cancellation.

Features of any given aspect or example embodiment may be combined with the features of any other aspect or example embodiment and the various features described herein may be implemented in any combination in a given embodiment.

Associated methods of fabricating a MEMS transducer are provided for each of the example embodiments.

It should be understood that the various relative terms above, below, upper, lower, top, bottom, underside, overlying, underlying, beneath, etc. that are used in the present description should not be in any way construed as limiting to any particular orientation of the transducer during any fabrication step and/or it orientation in any package, or indeed the orientation of the package in any apparatus. Thus the relative terms shall be construed accordingly.

In the examples described above it is noted that references to a transducer may comprise various forms of transducer element. For example, a transducer may be typically mounted on a die and may comprise a single membrane and back-plate combination. In another example a transducer die comprises a plurality of individual transducers, for example multiple membrane/back-plate combinations. The individual transducers of a transducer element may be similar, or configured differently such that they respond to acoustic signals differently, e.g. the elements may have different sensitivities. A transducer element may also comprise different individual transducers positioned to receive acoustic signals from different acoustic channels.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

1. A MEMS transducer configured to operate as a microphone, the MEMS transducer comprising a flexible membrane, the flexible membrane having a first surface and a second surface, wherein the first surface of the flexible membrane is fluidically isolated from the second surface of the flexible membrane.

2. The MEMS transducer of claim 1, wherein the flexible membrane further comprises an electromagnetic waveguide and is configured to operate as an optical microphone.

3. (canceled)

4. The MEMS transducer of claim 1, wherein the first surface of the flexible membrane and second surface of the flexible membrane are both circular.

5. The MEMS transducer of claim 1, wherein the flexible membrane has a dome structure.

6. The MEMS transducer of claim 1, further comprising a chamber, wherein the second surface of the flexible membrane partially defines the boundary of the chamber, and wherein the chamber is fluidically isolated from a region outside the chamber, wherein the chamber contains a constant amount of gas.

7. (canceled)

8. The MEMS transducer of claim 6, the constant amount of gas being set such that the chamber is at a lower pressure than the region outside the chamber when the MEMS transducer is at standard temperature and pressure, optionally wherein the constant amount of gas is substantially zero and the chamber is a vacuum.

9. The MEMS transducer of claim 8, wherein the gas has a lower mean molecular weight than air.

10.-11. (canceled)

12. The MEMS transducer of claim 6, wherein the chamber is a back volume of the microphone.

13. A MEMS device comprising the MEMS transducer of claim 1, the MEMS device further comprising a chamber, wherein the second surface of the flexible membrane partially defines the boundary of the chamber, and wherein the chamber is fluidically isolated from a region outside the chamber, wherein the chamber contains a constant amount of gas.

14. (canceled)

15. The MEMS device of claim 13, the constant amount of gas being set such that the chamber is at a lower pressure than the region outside the chamber when the MEMS device is at standard temperature and pressure, optionally wherein the constant amount of gas is substantially zero and the chamber is a vacuum.

16. The MEMS device of claim 15, wherein the gas has a lower mean molecular weight than air.

17.-18. (canceled)

19. The MEMS device of claim 13, wherein the chamber is a back volume of the microphone.

20. The MEMS device of claim 19, wherein a boundary of the back volume is partially defined by the flexible membrane and a substrate of the MEMS device.

21. The MEMS device of claim 20, wherein the substrate comprises a layer including at least a portion of the electronic circuitry of the microphone, the MEMS device being configured such that the flexible membrane at least partially overlies the portion of the electronic circuitry.

22. (canceled)

23. The MEMS device of claim 19, further comprising a package, wherein a boundary of the back volume is partially defined by the package.

24. The MEMS device of claim 23, wherein the package is a lid type package, or wherein the package is a laminate type package.

25. (canceled)

26. A MEMS transducer comprising a flexible membrane wherein the flexible membrane is configured to seal a chamber within the MEMS transducer, such that there is no fluid communication between the chamber and a region outside the chamber.

27. (canceled)

28. A packaged MEMS microphone comprising a MEMS transducer of claim 26.

29. A packaged MEMS optical microphone comprising a flexible membrane, the flexible membrane having a first surface and a second surface, the packaged MEMS optical microphone being configured such that the first surface of the flexible membrane is fluidically isolated from the second surface of the flexible membrane.

30.-36. (canceled)
